(19) United States
(12) Patent Application Publication
(10) Pub. No.: US 2023/0111566 A1
(43) Pub. Date: Apr. 13, 2023

(54) CONTROL METHOD OF WRITING APPARATUS AND WRITING APPARATUS

(71) Applicant: NuFlare Technology, Inc., Yokohama-shi (JP)

(72) Inventors: Eita FUJISAKI, Yokohama (JP); Takahito NAKAYAMA, Chigasaki (JP)

(73) Assignee: NuFlare Technology, Inc., Yokohama-shi (JP)

(21) Appl. No.: 17/962,825

(22) Filed: Oct. 10, 2022

(30) Foreign Application Priority Data
Oct. 13, 2021 (JP) 2021-168403

(51) Int. Cl. H01J 37/04; H01J 37/317; H01J 37/20; G03F 7/20

(52) U.S. Cl. CPC H01J 37/045; H01J 37/3177; H01J 37/20; G03F 7/7005; G03F 7/70525; H01J 2237/20221; H01J 2237/0435; H01J 2237/2001

(57) ABSTRACT

A writing apparatus of the embodiments of the present invention is a writing apparatus that irradiates a predetermined position on an irradiation target with multiple charged particle beams to write a predetermined pattern on the irradiation target, the apparatus comprising: a beam generation mechanism configured to generate multiple charged particle beams; a blanking aperture mechanism configured to perform blanking control of the generated multiple charged particle beams; a stage configured to have the irradiation target mounted thereon and to be movable; and a controller configured to control the writing apparatus, wherein the controller controls the blanking aperture mechanism and the stage to move the stage in an in-plane direction of a surface of the irradiation target during a blanking period in preparatory phase for writing.

### CROSS REFERENCE TO RELATED APPLICATIONS

This application is based upon and claims the benefit of priority from the prior Japanese Patent Application No. 2021-168403, filed on Oct. 13, 2021, the entire contents of which are incorporated herein by reference.

### FIELD

The embodiments of the present invention relate to a control method of a writing apparatus and a writing apparatus.

### BACKGROUND

A writing apparatus irradiates a mask blanks with a charged particle beam emitted from an electron source to expose a sensitive material on the mask blanks in a desired pattern. Desired multiple beams (multi-beams) are generated in the writing apparatus by passing the charged particle beam through a shaping aperture array that has an aperture array including many apertures.

### BRIEF DESCRIPTION OF THE DRAWINGS

FIG. 1 is a diagram illustrating a configuration example of a writing apparatus according to a first embodiment;

FIG. 2 is a flowchart illustrating an example of the control method of the writing apparatus according to the first embodiment;

FIG. 3 is a conceptual diagram illustrating an operation of the stage during the soaking processing;

FIG. 4 is a conceptual diagram illustrating an operation of the stage according to a second embodiment;

FIG. 5 is a conceptual diagram illustrating an operation of the stage according to a third embodiment; and

FIGS. 6 and 7 are flowcharts illustrating an example of a control method of the writing apparatus according to the third embodiment.

### DETAILED DESCRIPTION

Embodiments will now be explained with reference to the accompanying drawings. The present invention is not limited to the embodiments. In the present specification and the drawings, elements identical to those described in the foregoing drawings are denoted by like reference characters and detailed explanations thereof are omitted as appropriate.

A writing apparatus of the embodiments of the present invention is a writing apparatus that irradiates a predetermined position on an irradiation target with multiple charged particle beams to write a predetermined pattern on the irradiation target, the apparatus comprising: a beam generation mechanism configured to generate multiple charged particle beams; a blanking aperture mechanism configured to perform blanking control of the generated multiple charged particle beams; a stage configured to have the irradiation target mounted thereon and to be movable; and a controller configured to control the writing apparatus, wherein the controller controls the blanking aperture mechanism and the stage to move the stage in an in-plane direction of a surface of the irradiation target during a blanking period in preparatory phase for writing.

A control method of a writing apparatus according to the embodiments is a control method comprising: a beam generation mechanism configured to generate multiple charged particle beams; a blanking aperture mechanism configured to perform blanking control of the generated multiple charged particle beams; and a stage configured to have the irradiation target mounted thereon and to be movable, the method comprising continuously moving the stage in an in-plane direction of a surface of the irradiation target during a blanking period in preparatory phase for writing of the multiple charged particle beams.

### First Embodiment

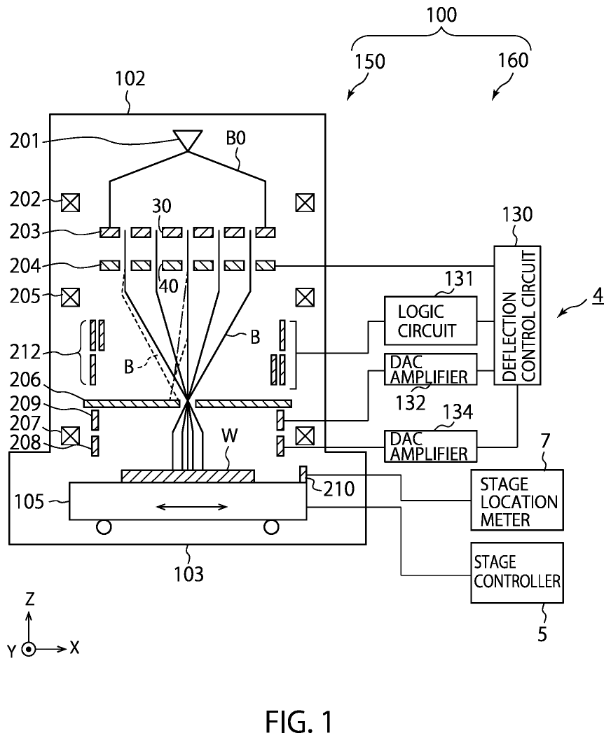

FIG. 1 is a diagram illustrating a configuration example of a writing apparatus according to a first embodiment. A writing apparatus 100 is, for example, a charged particle beam writing apparatus of a multi-beam system and is used for writing of a photomask or a template for lithography used in manufacturing of semiconductor devices. The present embodiment may be applied to an apparatus that irradiates a specimen W with a charged particle beam other than an electron beam, such as an ion beam. Therefore, the specimen W as an irradiation target may be a semiconductor substrate or the like, as well as the mask blanks.

The writing apparatus 100 includes a writing part 150 and a controller 160. The writing part 150 includes an electron lens barrel 102 and a writing chamber 103. The controller 160 includes an irradiation controller 4, a stage controller 5, and a stage location meter 7.

An electron source 201, an illuminating lens 202, a shaping aperture array substrate 203, a blanking aperture array mechanism 204, a reducing lens 205, a limiting aperture substrate 206, an objective lens 207, a main deflector 208, a sub deflector 209, and a blanking deflector 212 are placed in the electron lens barrel 102.

A stage 105 on which a specimen W, such as a mask blanks, being an irradiation target of multi-beams at the time of writing can be mounted is placed in the writing chamber 103. The specimen W is, for example, a mask blanks including a light-shielding film such as a chrome film and a resist film stacked on a glass substrate. The stage 105 can be moved in an in-plane direction of the surface of the specimen W, that is, in an X direction and a Y direction orthogonal to each other (a substantially horizontal direction). A mirror 210 is arranged on the stage 105 to measure the location of the stage 105. The inner portions of the electron lens barrel 102 and the writing chamber 103 are evacuated to be brought to a depressurized state.

The electron source 201 serving as a beam irradiating part generates a charged particle beam B0. The charged particle beam B0 is, for example, an electron beam or an ion beam. The specimen W is irradiated with the charged particle beam B0 generated by the electron source 201.

The shaping aperture array substrate 203 has a plurality of openings 30, for example, arrayed in m columns and n rows (m, n≥2) at a predetermined arrangement pitch. The openings 30 are formed in rectangles having the same dimension and the same shape, respectively. The shape of the openings 30 may be a circle. The charged particle beam B0 emitted from the electron source 201 is caused by the illuminating lens 202 to substantially perpendicularly illuminate the entire shaping aperture array substrate 203. The charged particle beam B0 illuminates a region including all the openings 30 of the shaping aperture array substrate 203. A part of the charged particle beam B0 passes the openings 30 to be shaped into multi-beams B. In this way, the shaping aperture array substrate 203 generates the multi-beams B by shaping the charged particle beam B0 from the electron source 201.

The blanking aperture array mechanism 204 includes a plurality of openings 40 to correspond to arrangement locations of the openings 30 of the shaping aperture array substrate 203, respectively. Although not illustrated, a pair of two electrodes (blankers) are arranged for each of the openings 40. The multi-beams B passing through the openings 40 are individually deflected by a voltage applied to each pair of the two electrodes. That is, the blankers perform blanking deflection of corresponding beams among the multi-beams B having passed through the openings 30 of the shaping aperture array substrate 203, respectively. Accordingly, the blanking aperture array mechanism 204 can perform ON/OFF control of beams individually for each of the multi-beams B having passed through the shaping aperture array substrate 203. That is, the blanking aperture array mechanism 204 can perform blanking control as to whether each of the multi-beams B is to be applied to the specimen W. The blanking aperture array mechanism 204 is controlled by a deflection control circuit 130. The openings 40 of the blanking aperture array mechanism 204 are larger than the openings 30 of the shaping aperture array substrate 203 and more easily pass each beam of the multi-beams B.

The blanking deflector 212 that performs collective blanking control of all the multi-beams is provided below the blanking aperture array mechanism 204. The blanking deflector 212 can perform blanking control as to whether all the multi-beams B are to be applied to the specimen W.

The limiting aperture substrate 206 having an opening formed in a central part is provided below the blanking deflector 212. Electron beams deflected by the blanking aperture array mechanism 204 or the blanking deflector 212 to be brought to a beam OFF state are deviated from the position of the opening at the center of the limiting aperture substrate 206 and are shielded by the limiting aperture substrate 206. This state in which the electron beams are shielded by the limiting aperture substrate 206 is referred to as “beam OFF”. Electron beams not having deflected by the blanking aperture array mechanism 204 and the blanking deflector 212 pass through the limiting aperture substrate 206 and are deflected by the deflectors 208 and 209 to be applied to desired positions on the specimen W. This state in which the electron beams pass through the limiting aperture substrate 206 to be applied to the specimen W is referred to as “beam ON”.

The blanking deflector 212 is controlled by a logic circuit 131 and the deflection control circuit 130 and performs blanking control as to whether the multi-beams B having passed through the openings of the blanking aperture array mechanism 204 are to be applied as a whole to the specimen W. Accordingly, the whole multi-beams B can be controlled to be beam ON or beam OFF without changing the control state of the blanking aperture array mechanism 204. The beam ON and the beam OFF are controlled by a blanking aperture mechanism including the blanking aperture array mechanism 204, the limiting aperture substrate 206, and the blanking deflector 212. The deflectors 208 and 209 are controlled by the deflection control circuit 130 via DAC (Digital-to-Analog Converter) amplifiers 132 and 134, respectively.

The controller 160 can be composed of one or a plurality of computers, CPUs (Central Processing Units), PLCs (Programmable Logic Controllers), or the like. The controller 160 may be composed integrally with the writing part 150 or may be formed as a separate body.

The stage controller 5 controls the operation of the stage 105 to move the stage 105 in the X direction or the Y direction (in a substantially horizontal direction).

The stage location meter 7 is composed of, for example, a laser length meter and irradiates the mirror 210 fixed on the stage 105 with laser light to measure the location of the stage 105 in the X direction on the basis of reflected light. Same components as the stage location meter 7 and the mirror 210 are provided also in the Y direction as well as in the X direction to also measure the location of the stage 105 in the Y direction.

FIG. 1 illustrates constituent elements necessary for explaining the first embodiment. The writing apparatus 100 may include other necessary constituent elements.

The writing apparatus 100 performs a writing operation by a raster scanning method in which shot beams are continuously and sequentially emitted while the stage 105 is moved. When a desired pattern is to be written, necessary beams according to the pattern are controlled to be beam ON or beam OFF by the blanking control.

A control method of the writing apparatus 100 according to the present embodiment is explained next.

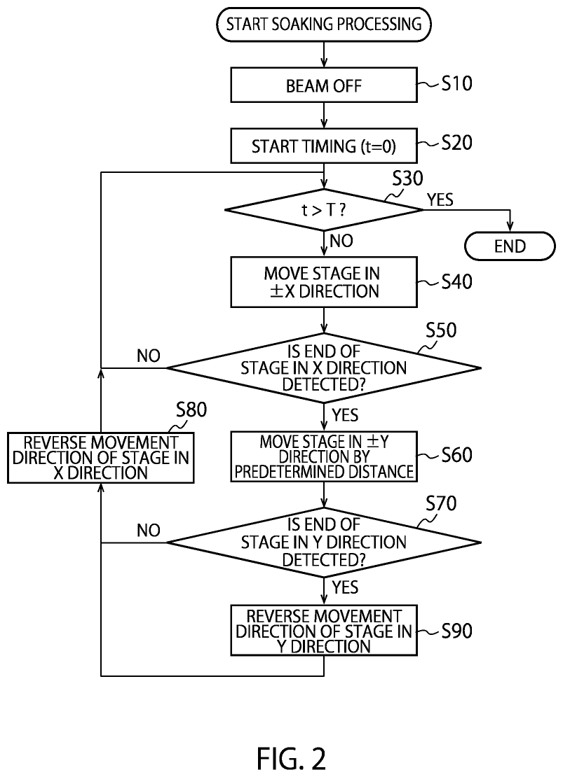

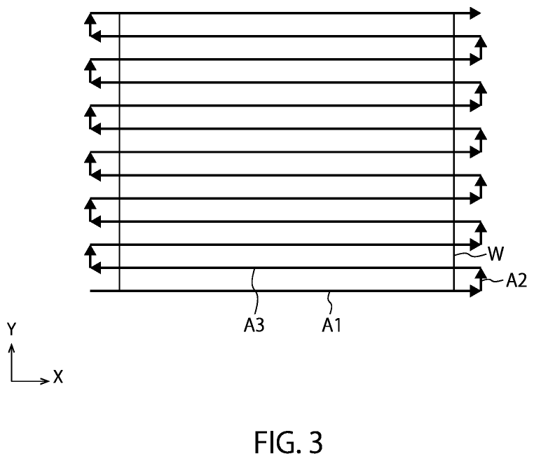

FIG. 2 is a flowchart illustrating an example of the control method of the writing apparatus 100 according to the first embodiment. The flow of FIG. 2 illustrates soaking processing at a preparatory stage before writing. FIG. 3 is a conceptual diagram illustrating an operation of the stage 105 during the soaking processing.

The soaking processing is processing of waiting until the temperature of the specimen W matches the temperature of the stage 105 in the writing chamber 103 after the specimen W such as a mask blanks is mounted on the stage 105. In the soaking processing, the multi-beams B are brought to the beam OFF state by the blanking deflector 212 to prevent the specimen W from being irradiated with the multi-beams B. Therefore, the multi-beams B are shielded by the limiting aperture substrate 206 and do not reach the specimen W.

However, some of leaked beams such as scattered electrons cannot be sufficiently shielded by the blanking aperture array mechanism 204 and the blanking deflector 212 in some cases. There is a risk that some of these leaked beams pass through the blanking aperture array mechanism 204 and the blanking deflector 212 to be applied to the specimen W. In such a case, when the specimen W remains still and the leaked beams are locally applied to a sensitive material, the sensitive material is unintentionally locally exposed to the leaked beams.

In order to solve this problem, in the present embodiment, the stage controller 5 continuously moves the stage 105 to prevent the specimen W from being locally exposed, for example, during a period (blanking period) in which the blanking aperture array mechanism 204 or the blanking deflector 212 is performing blanking control of the multi-beams B in preparatory phase for writing.

First, the blanking aperture array mechanism 204 and/or the blanking deflector 212 deflect the multi-beams B to be applied to the limiting aperture substrate 206 and cause the beams to be OFF (S10).

Next, a time t is reset to 0 (zero) to start timing (S20). For example, the deflection control circuit 130 or the stage controller 5 includes a timer (not illustrated) and measures the time t from start of the soaking processing. The time t is measured from zero. A soaking processing time T is a time from when a specimen W is mounted on the stage 105 until when the temperature of the specimen W becomes a predetermined temperature substantially equal to the temperature of the stage 105 (a time to reach a state of equilibrium) and is set in advance. The soaking processing is continued until the time t reaches the soaking processing time T.

The deflection control circuit 130 or the stage controller 5 compares the time t with the soaking processing time T (S30). When the time t has not reached the soaking processing time T (NO at S30), the stage controller 5 continuously moves the stage 105 in the substantially horizontal plane (in the X-Y plane). For example, the stage controller 5 moves the stage 105 in the +X direction or the −X direction (S40). For example, as indicated by an arrow A1 in FIG. 3, the stage controller 5 moves the stage 105 in the +X direction. The stage location meter 7 measures the location of the stage 105 and processes at Steps S30 to S50 are repeated until the stage 105 moves to an end in the +X direction or the −X direction (NO at S50). That is, the stage controller 5 continuously moves the stage 105 to an end in the +X direction or the −X direction. The end can be an end in a movable range of the stage controller 5.

When an end of the stage 105 in the +X direction or the −X direction is detected (YES at S50), the stage controller 5 moves the stage 105 in the +Y direction or the −Y direction by a predetermined distance (S60). For example, as indicated by an arrow A2 in FIG. 3, the stage controller 5 moves the stage 105 in the +Y direction. It suffices that the predetermined distance is such a distance that prevents the leaked beams from overlapping and the predetermined distance may have, for example, a size substantially equal to an aperture opening diameter of the limiting aperture substrate 206.

Subsequently, when an end of the stage 105 in the Y direction is not detected yet (NO at S70), the stage controller 5 reverses the movement direction of the stage 105 in the X direction (S80). That is, when the movement direction of the stage 105 is the +X direction at Step S40, the stage controller 5 changes the movement direction of the stage 105 to the −X direction. When the movement direction of the stage 105 is the −X direction at Step S40, the stage controller 5 changes the movement direction of the stage 105 to the +X direction. For example, as indicated by an arrow A3 in FIG. 3, the stage controller 5 reverses the movement direction of the stage 105 to change from the +X direction to the −X direction. The processes at Steps S30 to S50 are then repeated (NO at S50).

When an end of the stage 105 in the +X direction or the −X direction is detected again (YES at S50), the processes at Steps S60 and S70 are performed, in which the stage controller 5 moves the stage 105 in the +Y direction or the −Y direction by the predetermined distance. Further, the stage controller 5 reverses the movement direction of the stage 105 in the X direction at Step S80.

By the processes at Steps S30 to S80 repeatedly performed in this way, the stage 105 reciprocates in the ±X directions while moving in the Y direction the predetermined distance by the predetermine distance. That is, as illustrated in FIG. 3, the stage controller 5 continuously moves the stage 105 in a zigzag manner (like hairpin curves) during the soaking processing time T. In this way, the stage controller 5 moves the stage 105 to prevent as much as possible the stage 105 from passing the same location (a certain static position in the writing chamber 103).

When an end of the stage 105 in the Y direction is detected (YES at S70), the stage controller 5 reverses the movement direction of the stage 105 in the Y direction (S90). That is, when the movement direction of the stage 105 is the +Y direction at Step S60, the stage controller 5 changes the movement direction of the stage 105 to the −Y direction at Step S90. When the movement direction of the stage 105 is the −Y direction at Step S60, the stage controller 5 changes the movement direction of the stage 105 to the +Y direction at Step S90. Subsequently, the processes at Steps S80 and S30 to S70 are repeated. That is, when the stage 105 reaches an end in the Y direction, the stage 105 turns back in the opposite direction in the Y direction and returns again in a zigzag manner in the ±X directions while moving the predetermined distance by the predetermined distance. For example, the stage 105 can move to follow the arrows in FIG. 3 in the opposite direction. In this way, the stage controller 5 continuously moves the stage 105 during the soaking processing time T without stopping the stage 105. In this case, the stage 105 passes the same location plural times. However, since the specimen W is almost uniformly exposed to the leaked beams, local exposure can be suppressed.

When the time t reaches the soaking processing time T at Step S30 (YES at S30), the soaking processing ends. Subsequently, as preparation before drawing, the deflection control circuit 130 measures the height (the location in the Z direction) of the surface of the specimen W and performs mapping to measure distortion of the specimen W (Z-map measurement). Also in the Z-map measurement, the writing apparatus 100 is in a beam OFF state. Therefore, it is preferable that the stage controller 5 continuously moves the stage 105 in a zigzag manner likewise.

As described above, the writing apparatus 100 according to the present embodiment continuously moves the stage 105 in a substantially horizontal plane (the X-Y plane) during the soaking processing time T. At this time, the stage controller 5 moves the stage 105 to prevent the stage 105 from passing the same location. For example, the stage controller 5 reciprocates the stage 105 in a zigzag manner in the ±X directions while moving the stage 105 in the Y direction the predetermined distance by the predetermined distance. Accordingly, the leaked beams are distributed on the whole surface of the specimen W without being locally applied to a specific part of the specimen W. Therefore, the sensitive material of the specimen W is suppressed from being locally exposed to the leaked beams and influences of the leaked beams on the writing processing can be consequently reduced. This leads to an improvement in the reliability of a pattern formed on the surface of a specimen W.

### Second Embodiment

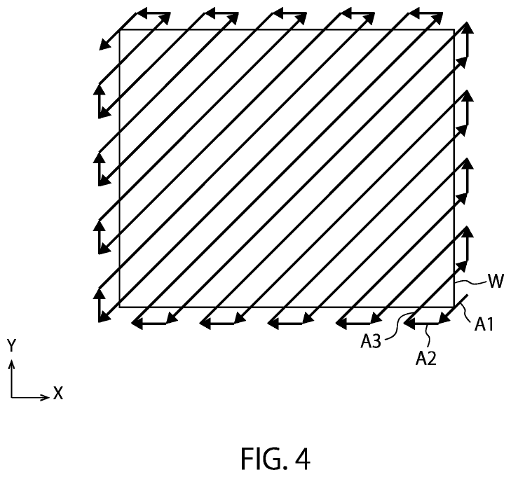

FIG. 4 is a conceptual diagram illustrating an operation of the stage 105 according to a second embodiment. In the second embodiment, the stage controller 5 reciprocates the stage 105 in a zigzag manner in an oblique direction to the X and Y directions (the sides of the specimen W).

For example, at Step S40 in FIG. 2, the stage controller 5 moves the stage 105 in an oblique direction to the X and Y directions (in the direction of an arrow A1 in FIG. 4).

When an end of the stage 105 is detected at Step S50 (YES at S50), the stage controller 5 moves the stage 105 in the −X direction (the direction of an arrow A2 in FIG. 4) by a predetermined distance at Step S60.

Next, the movement direction of the stage 105 is reversed to a direction (the direction of an arrow A3) opposite to the movement direction (the direction of the arrow A1) of the stage 105 at Step S40.

When an end of the stage 105 in the +X direction or the −X direction is detected again (YES at S50), the stage controller 5 moves the stage 105 in the +Y direction by the predetermined distance. Further, the stage controller 5 reverses the movement direction of the stage 105 at Step S80.

By repeating the processes at Steps S30 to S80 in this way, the stage 105 reciprocates in the oblique direction to the X and Y directions while alternately moving in the −X and +Y directions by the predetermined distance. That is, as illustrated in FIG. 4, the stage controller 5 continuously moves the stage 105 in a zigzag manner (like hairpin curves) in the oblique direction to the sides of the specimen W during the soaking processing time T. In this way, the stage controller 5 moves the stage 105 to prevent as much as possible the stage 105 from passing the same location.

Also in the second embodiment, when the stage 105 reaches the other end in the oblique direction, the stage 105 may turn back in the opposite direction to the oblique direction and return again in a zigzag manner. For example, when the stage 105 reaches from one end to the other end in the oblique direction, the stage 105 may move to follow the arrows in FIG. 4 in the opposite direction. In this way, the stage controller 5 continuously moves the stage 105 during the soaking processing time T without stopping the stage 105. In this case, the stage 105 passes the same location plural times. However, since the specimen W is almost uniformly exposed to the leaked beams, local exposure can be suppressed.

Other operations of the second embodiment may be identical to corresponding operations of the first embodiment. Further, the configuration of the writing apparatus 100 according to the second embodiment may be identical to that of the first embodiment. Therefore, the second embodiment can obtain effects identical to those of the first embodiment.

### Third Embodiment

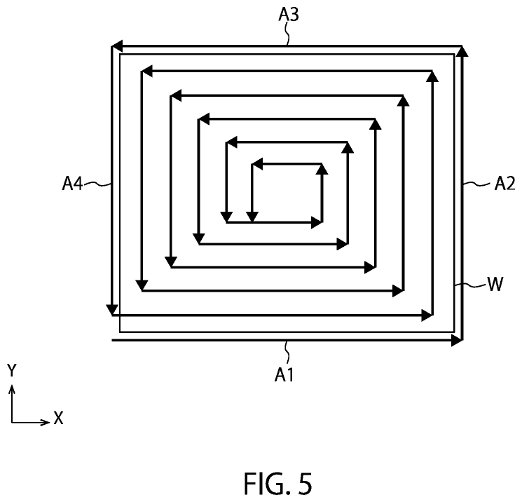

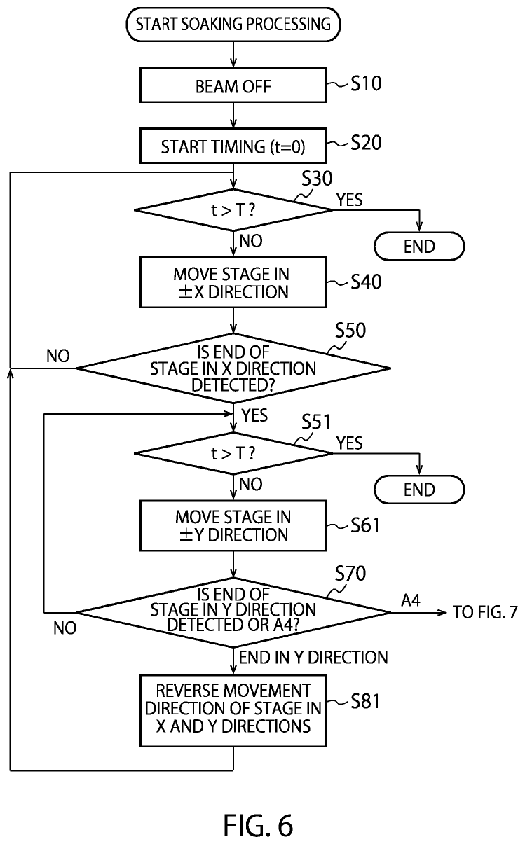

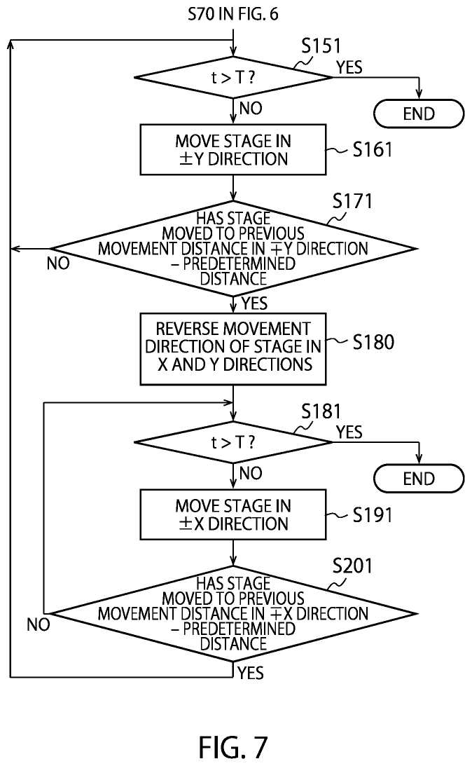

FIG. 5 is a conceptual diagram illustrating an operation of the stage 105 according to a third embodiment. In the third embodiment, the stage controller 5 moves the stage 105 in a spiral manner. FIGS. 6 and 7 are flowcharts illustrating an example of a control method of the writing apparatus 100 according to the third embodiment. The flows of FIGS. 6 and 7 illustrate the soaking processing at a preparatory stage before writing.

Processes at Steps S10 to S50 in FIG. 6 may be same as those at Steps S10 to S50 in FIG. 2. Therefore, for example, at Step S40, the stage controller 5 moves the stage 105 in the +X direction (the direction of an arrow A1 in FIG. 5) until an end of the stage 105 is detected (NO at S50).

When an end of the stage 105 is detected at Step S50 (YES at S50), the time t is compared with the soaking processing time T at Step S51 similarly to Step S30. When the time t has not reached the soaking processing time T (NO at S51), the stage controller 5 moves the stage 105 in the +Y direction (the direction of an arrow A2 in FIG. 5) until an end of the stage 105 is detected (NO at S70).

When an end of the stage 105 is then detected (an end in the Y direction at S70), the stage controller 5 reverses the movement direction of the stage 105 in the X direction and the Y direction. That is, the stage controller 5 changes the movement direction of the stage 105 to the −X direction (the direction of an arrow A3 in FIG. 5) and the −Y direction (the direction of an arrow A4 in FIG. 5) (S81).

The processes at Steps S30 to S70 are subsequently repeated. Since the movement direction of the stage 105 is reversed both in the X and Y directions, the stage controller 5 moves the stage 105 in the −X direction (the direction of the arrow A3 in FIG. 5) at Step S40. At step S61, the stage controller 5 moves the stage 105 in the −Y direction (the direction of the arrow A4 in FIG. 5).

When the stage 105 is moving along the arrow A4 in FIG. 5 at Step S70, the processing proceeds to the flow of FIG. 7. The time t is compared with the soaking processing time T at Step S151 in FIG. 7. When the time t has not reached the soaking processing time T (NO at S151), the stage controller 5 moves the stage 105 in the −Y direction (the direction of the arrow A4 in FIG. 5).

At this time, the stage controller 5 moves the stage 105 by a distance that is a predetermined distance shorter than the previous movement distance in the direction of the arrow A2. That is, the stage controller 5 detects whether the stage 105 has moved by a distance that is obtained by subtracting the predetermined distance from the previous movement distance in the opposite direction (the +Y direction) (S171).

When the stage 105 has not reached the distance obtained by subtracting the predetermined distance from the previous movement distance in the opposite direction (the +Y direction) (NO at S171), the processes at Steps S151 and S161 are repeated, in which the stage controller 5 continuously moves the stage 105 in the −Y direction (the direction of the arrow A4 in FIG. 5).

When the stage 105 has reached the distance obtained by subtracting the predetermined distance from the previous movement distance in the opposite direction (the +Y direction) (YES at S171), the stage controller 5 reverses the movement direction of the stage 105 in the X direction and the Y direction (S180). That is, the stage controller 5 changes the movement direction of the stage 105 to the +X direction and the +Y direction.

The stage controller 5 compares the time t with the soaking processing time T (S181). When the time t has not reached the soaking processing time T (NO at S181), the stage controller 5 moves the stage 105 in the +X direction (S191).

At this time, the stage controller 5 moves the stage 105 by a distance that is the predetermined distance shorter than the previous movement distance in the direction of the arrow A3. That is, the stage controller 5 detects whether the stage 105 has moved by a distance that is obtained by subtracting the predetermined distance from the previous movement distance in the opposite direction (the −X direction) (S201).

When the stage 105 has not reached the distance obtained by subtracting the predetermined distance from the previous movement distance in the opposite direction (the −X direction) (NO at S201), the processes at Steps S181 and S191 are repeated, in which the stage controller 5 continuously moves the stage 105 in the +X direction.

When the stage 105 has reached the distance obtained by subtracting the predetermined distance from the previous movement distance in the opposite direction (the −X direction) (YES at S201), the processes at Steps S151 to S201 are repeated.

In this way, the stage controller 5 moves the stage 105 by a distance that is the predetermined distance shorter than the previous movement distance in the opposite direction while reversing the movement direction of the stage 105 both in the X and Y directions. Accordingly, the stage 105 moves in a spiral manner as illustrated in FIG. 5.

For example, the stage controller 5 moves the stage 105 in the +X direction again in the process at Step S191 described above. At this time, the stage controller 5 moves the stage 105 by a distance that is the predetermined distance shorter than the previous movement distance in the direction of the arrow A3.

Subsequently, the stage controller 5 moves the stage 105 in the +Y direction again. At this time, the stage controller 5 moves the stage 105 by a distance that is the predetermined distance shorter than the previous movement distance in the direction of the arrow A4.

Next, the stage controller 5 moves the stage 105 in the −X direction again. At this time, the stage controller 5 moves the stage 105 by a distance that is the predetermined distance shorter than the previous movement distance in the direction of the arrow A1.

Next, the stage controller 5 moves the stage 105 in the −Y direction again. At this time, the stage controller 5 moves the stage 105 by a distance that is the predetermined distance shorter than the previous movement distance in the direction of the arrow A2.

In this way, the stage controller 5 repeatedly moves the stage 105 in the +X direction, the +Y direction, the −X direction, and the −Y direction while shortening the movement distance of the stage 105 the predetermined distance by the predetermined distance. Accordingly, the stage 105 moves in a spiral manner as illustrated in FIG. 5.

It suffices that the stage controller 5 reverses the movement direction of the stage 105 when the stage 105 reaches a central position (for example, the origin). For example, the stage 105 can move to follow the arrows in FIG. 5 in the opposite direction. In this case, the stage 105 passes the same location plural times. However, since the specimen W is substantially uniformly exposed to leaked beams, local exposure can be suppressed. The configuration of the writing apparatus 100 according to the third embodiment may be identical to that of the first embodiment.

As described above, the effect of the present embodiment is not lost even when the stage 105 is moved in a spiral manner. Also in the third embodiment, the stage controller 5 continuously moves the stage 105 during the soaking processing time T without stopping the stage 105. Therefore, the third embodiment can obtain identical effects as those of the first embodiment.

### First Modification

Although not illustrated, the stage 105 may be moved in a random manner. Even when the stage 105 is moved in a random manner, the stage controller 5 moves the stage 105 to prevent as much as possible the stage 105 from passing the same location. Accordingly, even when the stage 105 is moved in a random manner, effects of the embodiments are not lost.

### Second Modification

Leaked beams are sometimes applied at a high intensity to just below the optical axis of the multi-beams B. Therefore, it is preferable that the stage controller 5 moves the stage 105 in such a manner that the stage 105 does not pass just below the optical axis of the multi-beams B during the soaking processing time T. While the movement range of the stage 105 is limited in this case, exposure to the leaked beams can be effectively suppressed.

### Third Modification

The first to third embodiments and the first and second modifications are embodiments in the soaking processing. However, any of the first to third embodiments and the first and second modifications can be applied also to Z-map measurement processing. Furthermore, any of the first to third embodiments and the first and second modifications can be applied to a period between writing processing and writing processing of the multi-beams B, or a period in which beams in a region in which no pattern is formed are OFF. For example, when the specimen W is to be irradiated with the multi-beams B, the multi-beams B are applied along a plurality of lines on the surface of the specimen W. The beams are OFF in a period from when irradiation of a first line among the lines ends until when irradiation of the subsequent second line is started. Any of the first to third embodiments and the first and second modifications may be applied in this period in which the beams are OFF. That is, any of the first to third embodiments and the first and second modifications can be applied to any period in which the beams are OFF.

In the first to third embodiments and the first to third modifications, the movement speed of the stage 105 is preferably higher than the movement speed (an average speed in the case of variable speed writing) at the time of writing (in a period in which the beams are ON) to effectively suppress exposure to the leaked beams.

While certain embodiments have been described, these embodiments have been presented by way of example only, and are not intended to limit the scope of the inventions. Indeed, the novel methods and systems described herein may be embodied in a variety of other forms; furthermore, various omissions, substitutions and changes in the form of the methods and systems described herein may be made without departing from the spirit of the inventions. The accompanying claims and their equivalents are intended to cover such forms or modifications as would fall within the scope and spirit of the inventions.

1. A writing apparatus that irradiates a predetermined position on an irradiation target with multiple charged particle beams to write a predetermined pattern on the irradiation target, the apparatus comprising:
a beam generation mechanism configured to generate multiple charged particle beams;
a blanking aperture mechanism configured to perform blanking control of the generated multiple charged particle beams;
a stage configured to have the irradiation target mounted thereon and to be movable; and
a controller configured to control the writing apparatus, wherein the controller controls the blanking aperture mechanism and the stage to move the stage in an in-plane direction of a surface of the irradiation target during a blanking period in preparatory phase for writing.

2. The apparatus of claim 1, further comprising a blanker configured to blank the multiple charged particle beams in a lump.

3. The apparatus of claim 1, wherein the controller moves the stage so as not to pass a same location during the blanking period.

4. The apparatus of claim 1, wherein the controller moves the stage during the blanking period without stopping the stage.

5. The apparatus of claim 1, wherein the controller performs soaking for uniformizing temperatures on the irradiation target during the blanking period.

6. The apparatus of claim 1, wherein the controller continuously moves the stage in a substantially horizontal plane during the blanking period.

7. The apparatus of claim 1, wherein the controller moves the stage in a zigzag manner, a spiral manner, or a random manner during the blanking period.

8. The apparatus of claim 1, wherein the controller moves the stage so as not to pass just below an optical axis of the multiple charged particle beams during the blanking period.

9. The apparatus of claim 1, wherein the blanking period is a period from when the irradiation target is mounted on the stage until when the irradiation target reaches a predetermined temperature.

10. The apparatus of claim 1, wherein
the multiple charged particle beams are applied along a plurality of lines on the irradiation target when the irradiation target is irradiated with the multiple charged particle beams, and
the blanking period is a period from when irradiation on a first line among the lines is ended until irradiation on a subsequent second line is started.

11. A control method of a writing apparatus comprising:
a beam generation mechanism configured to generate multiple charged particle beams;
a blanking aperture mechanism configured to perform blanking control of the generated multiple charged particle beams; and
a stage configured to have the irradiation target mounted thereon and to be movable, the method comprising
continuously moving the stage in an in-plane direction of a surface of the irradiation target during a blanking period in preparatory phase for writing of the multiple charged particle beams.

12. The method of claim 11, wherein the stage is moved so as not to pass a same location during the blanking period.

13. The method of claim 11, wherein the stage is moved without stopping during the blanking period.

14. The method of claim 11, wherein soaking is performed for uniformizing temperatures on the irradiation target during the blanking period.

15. The method of claim 11, wherein the stage is continuously moved in a substantially horizontal plane during the blanking period.

16. The method of claim 11, wherein the stage is moved in a zigzag manner, a spiral manner, or a random manner during the blanking period.

17. The method of claim 11, wherein the stage is moved so as not to pass just below an optical axis of the multiple charged particle beams during the blanking period.

18. The method of claim 11, wherein the blanking period is a period from when the irradiation target is mounted on the stage until when the irradiation target reaches a predetermined temperature.

19. The method of claim 11, wherein
the multiple charged particle beams are applied along a plurality of lines on the irradiation target when the irradiation target is irradiated with the multiple charged particle beams, and
the blanking period is a period from when irradiation on a first line among the lines is ended until irradiation on a subsequent second line is started.
